(19) United States
(12) Patent Application Publication
(10) Pub. No.: US 2024/0055334 A1
(43) Pub. Date: Feb. 15, 2024

(54) TRANSFER MOLDED POWER MODULES AND METHODS OF MANUFACTURE

(71) Applicant: SEMICONDUCTOR COMPONENTS INDUSTRIES, LLC, Scottsdale, AZ (US)

(72) Inventors: Seungwon IM, Bucheon (KR); Oseob JEON, Seoul (KR); Jihwan KIM, Seoul (KR); Dongwook KANG, Bucheon (KR)

(73) Assignee: SEMICONDUCTOR COMPONENTS INDUSTRIES, LLC, Scottsdale, AZ (US)

(21) Appl. No.: 18/354,863

(22) Filed: Jul. 19, 2023

Related U.S. Application Data
(60) Provisional application No. 63/370,859, filed on Aug. 9, 2022.

(51) Int. Cl. H01L 23/498; H01L 23/31; H01L 21/48; H01L 21/56

(52) U.S. Cl. CPC H01L 23/49811; H01L 23/3121; H01L 21/4853; H01L 21/56

(57) ABSTRACT

In a general aspect, an electronic device assembly includes a circuit including at least one semiconductor die, and a signal lead electrically coupled with the circuit. The signal lead has a hole defined therethrough. The assembly further includes an electrically conductive signal pin holder disposed in the hole of the signal lead. The electrically conductive signal pin holder is electrically coupled with the signal lead. The assembly also includes a molding compound encapsulating, at least, the circuit; a portion of the signal lead including the hole; and a portion of the electrically conductive signal pin holder. An open end of the electrically conductive signal pin holder is accessible outside the molding compound.

### RELATED APPLICATION

This application claims priority to and the benefit of U.S. Provisional Application No. 63/370,859, filed on Aug. 9, 2022, entitled “ELECTRONIC DEVICE AND METHOD OF INTERCONNECTION OF TOP AND BOTTOM,” the disclosure of which is incorporated by reference herein in its entirety.

### TECHNICAL FIELD

This description relates to electronic device assemblies. More specifically, this description relates to semiconductor device modules, such as power semiconductor device modules.

### BACKGROUND

Semiconductor devices (e.g., semiconductor die) can be included in package assemblies or modules, where such modules can include signal pins, which can be configured for press-fit insertion or solder attachment in a corresponding system. Such signal pins can be inserted, e.g., press-fit, into signal pin holders (sleeves, cylinders, etc.) included in the module. Such signal pin holders can be coupled, both physically and electrically, to a circuit of the module, such as to a substrate on which a semiconductor device circuit is implemented. A molding operation, e.g., using an epoxy molding compound, can be performed to encapsulate components of the module, such as a semiconductor device circuit, portions of the substrate on which the semiconductor circuit is implemented (disposed, produced, etc.), and portions of the signal pin holders. For instance, openings, such as open ends of the signal holders for receiving respective signal pins can be exposed through the molding compound, where the signal pins are inserted after performing the molding operation. In some implementations, the circuit, or semiconductor device circuit, can be, or can include a single semiconductor device.

In prior implementations, signal pin holders are coupled to a substrate of the module, such as via a solder connection, then a molding operation can be performed, e.g., with respective openings of the holders being accessible through, or from outside an epoxy molding compound applied during the molding operation. Previous approaches have certain drawbacks, however. For instance, attachment of the signal pin holders can have alignment and/or to tilt issues, which causes variation in the respective locations of signal pin holder openings from their expected locations in an associated module. This variation can cause, or exacerbate complications with signal pin insertion, such as with automated signal pin insertion. For instance, insertion of signal pins in the holders, even in properly aligned signal pin holders, causes mechanical stresses that can result in cracking of the epoxy molding compound disposed around the holders. These signal pin insertion stresses can increase as a result of signal pin holder misalignment. Additionally, thermal cycling of the part over its operational lifetime (or in reliability testing) can also cause cracking in the molding compound surrounding the holders. Such cracking can lead to failure of the associated module, such as due to moisture penetration into module, or other reliability issues.

### SUMMARY

In a general aspect, an electronic device assembly includes a circuit including at least one semiconductor die, and a signal lead electrically coupled with the circuit. The signal lead has a hole defined therethrough. The assembly further includes an electrically conductive signal pin holder disposed in the hole of the signal lead. The electrically conductive signal pin holder is electrically coupled with the signal lead. The assembly also includes a molding compound encapsulating, at least, the circuit, a portion of the signal lead including the hole, and a portion of the electrically conductive signal pin holder. An open end of the electrically conductive signal pin holder is accessible (e.g., exposed) outside the molding compound.

Implementations can include one or more of the following features, alone or in combination. For example, the open end of the electrically conductive signal pin holder can be a first end. The circuit can include a substrate, and the electrically conductive signal pin holder can include a second end that is disposed on the substrate. The second end of the electrically conductive signal pin holder can be coupled with the substrate via a solder connection. The second end can be closed and disposed within the molding compound.

The open end of the electrically conductive signal pin holder can be coplanar with a surface of the molding compound.

The electrically conductive signal pin holder can be cylindrical and configured to a receive a signal pin by press-fit insertion.

The electrically conductive signal pin holder can be fixedly positioned in the hole of the signal lead by a frictional connection.

The open end of the electrically conductive signal pin holder can include a flange. A first surface of the flange can be disposed on the signal lead. A second surface of the flange, opposite the first surface, can be coplanar with a surface of the molding compound.

The signal lead and the electrically conductive signal pin holder can include at least one of copper or a copper alloy.

In another general aspect, an electronic device assembly includes a substrate arranged in a plane, the substrate having a first side and a second side, the second side being opposite the first side. The assembly also includes at least one semiconductor die disposed on the first side of the substrate, and an electrically conductive signal pin holder. The pin holder includes a proximal portion coupled with the first side of the substrate, and a distal portion. At least a portion of the electrically conductive signal pin holder is pre-molded in a stress buffer material, and the electrically conductive signal pin holder is arranged along a longitudinal axis that is orthogonal to the plane of the substrate.

Implementations can include one or more of the following features, alone or in combination. For example, the distal portion of the electrically conductive signal pin holder can be pre-molded in the stress buffer material, and the proximal portion of the electrically conductive signal pin holder can exclude the stress buffer material.

The proximal portion of the electrically conductive signal pin holder can include a flange. The flange can be coupled to the first side of the substrate via a solder connection.

The assembly can include a molding compound encapsulating the substrate, the at least one semiconductor die, and the electrically conductive signal pin holder, such that a surface of the stress buffer material is exposed through the molding compound. An open end of the electrically conductive signal pin holder can be exposed through the stress buffer material.

The stress buffer material can have a modulus of elasticity that is less than a modulus of elasticity of the electrically conductive signal pin holder, and less than a modulus of elasticity of the molding compound.

The electrically conductive signal pin holder can have a modulus of elasticity of greater than or equal to 100 giga-pascals (GPa). The molding compound can have a modulus of elasticity of greater than or equal to 15 GPa. The stress buffer material can have a modulus of elasticity of less or equal to 5 GPa.

The electrically conductive signal pin holder can be cylindrical and configured to a receive a signal pin by press-fit insertion.

The stress buffer material can include one of a rubber material; a polyphenylene sulfide material; or an engineering plastics material.

The electrically conductive signal pin holder can include at least one of copper, or a copper alloy.

In another general aspect, a method of forming an electronic device assembly includes producing, on a substrate, a semiconductor device circuit, and coupling a signal lead with the substrate. The signal lead has a hole defined therethrough. The method further includes press-fitting an electrically conductive signal pin holder in the hole of the signal lead, and performing a molding operation. The molding operation encapsulates, in a molding compound, at least the semiconductor device circuit, a portion of the signal lead including the hole, and a portion of the electrically conductive signal pin holder. An open end of the electrically conductive signal pin holder is accessible outside the molding compound.

Implementations can include one or more of the following features, alone or in combination. For example, the method can include press-fitting a signal pin into the electrically conductive signal pin holder via the open end.

The open end of the electrically conductive signal pin holder can be a first end. The method can include coupling a second end of the electrically conductive signal pin holder to the substrate via a solder connection.

The portion of the signal lead including the hole can be a first portion. The method can include, after the molding operation, trimming the signal lead to remove a portion of the signal lead that is external to the molding compound.

### BRIEF DESCRIPTION OF THE DRAWINGS

FIG. 1 is a diagram illustrating an isometric view of an example semiconductor device assembly.

FIG. 2 is a diagram illustrating an isometric view of an example implementation of the assembly of FIG. 1.

FIGS. 3A and 3B are diagrams illustrating various views of example signal pin holders in a semiconductor device assembly, such as the assemblies of FIGS. 1 and 2.

FIGS. 4A and 4B are diagrams illustrating various of views of other example signal pin holders in a semiconductor device assembly, such as the assembly of FIG. 1.

FIGS. 5A to 5C are diagrams illustrating various view of an example signal pin holder that is pre-molded with a stress buffer material.

FIG. 6 is diagram illustrating an isometric view of an example semiconductor device assembly that includes the signal pin holder of FIGS. 5A-5C.

FIGS. 7A to 7C are diagrams illustrating various view of another example signal pin holder that is pre-molded with a stress buffer material.

FIG. 8 is diagram illustrating an isometric view of an example semiconductor device assembly that includes the signal pin holder of FIGS. 7A-7C.

FIGS. 9A to 9C are diagrams illustrating various view of yet another an example signal pin holder that is pre-molded with a stress buffer material.

FIG. 10 is diagram illustrating an isometric view of still another example semiconductor device assembly that includes the signal pin holder of FIGS. 9A-9C.

FIGS. 11A to 11D are diagrams illustrating examples of other signal pin holders that are pre-molded with a stress buffer material.

FIG. 12 is a flowchart illustrating a method for producing a semiconductor assembly, such as, e.g., the assemblies of FIGS. 1, 2, 3A-3B, 4A-4B, 6, 8 and 10.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

This disclosure relates to packaged semiconductor device apparatuses, which can be referred to as modules, assemblies, semiconductor device modules, power semiconductor device modules, semiconductor device assemblies, electronic device assemblies, etc., as well as associated methods for producing such apparatuses. The approaches illustrated and described herein can be used to implement molded (e.g., transfer molded) semiconductor device modules that can overcome at least some of the drawbacks of prior approaches discussed above. In some implementations, the described approaches can be used to implement a half-bridge power module, a full-bridge power module, a 3-phase half-bridge power module, a multi-phase half-bridge power module, etc.

In example implementations described herein, signal pins of a semiconductor assembly can be signal pins that are press-fit into signal pin holders that are disposed in holes (through-holes) defined in signal leads of a leadframe, such as in widened portions of the signal lead structure (e.g., wider than a portion connected to a substrate or to a printed circuit board (PCB) of the module). In some implementations, the signal pin holders can be formed of copper (Cu), a copper alloy, such as copper molybdenum (CuMo), or one or more other electrically conductive materials. Respective diameters of the hole in the signal lead and the signal pin holder can be selected such that the signal pin holder is secured (e.g., fixedly positioned), and electrically coupled to the signal lead via a frictional (e.g., press-fit) connection. In some implementations, the hole can be or can define a lumen. In some implementations, the hole can be a opening define therethrough.

For a given signal pin holder, one end of the signal pin holder, e.g., an open end, can be exposed through a molding compound of an associated module to facilitate receipt of a signal pin, while a second end of the signal pin holder, e.g., a closed end, can be soldered to a substrate of the module within epoxy molding compound (EMC) of the module. For instance, the second end of the signal pin holder can be soldered to a direct-bonded metal (DBM) substrate, such as direct-bonded copper (DBC) substrate, a PCB included in an associated module, etc.

In some implementations, a second (closed) end of the signal pin holder can be disposed (encapsulated) in the EMC without being coupled to a substrate (e.g., a DBM substrate, a DBC substrate, a PCB, etc.). In some implementations a signal lead(s) having through-holes in which signal pin holders are inserted, can be included in a single-body leadframe with power tabs of an associated module (e.g., positive power supply tab(s), negative power supply tabs(s), and/or output signal tabs(s), such as for a switching node of a half-bridge circuit).

An inserted signal pin can then extend, e.g., orthogonally, from a primary surface of the molding compound of the module. In such implementations, variation of alignment of the signal pin holders (e.g., due to tilting, etc.) can be reduced or prevented, as insertion of the signal pin holder in a through-hole defined in a signal lead can improve alignment of the signal pin holder as compared to prior implementations. Accordingly, cracking of an EMC used for encapsulating portions of an associated module as a result of stresses associated with insertion of signal pins in misaligned signal pin holders can be reduced, or prevented as compared to prior implementations.

Further, in example implementations described herein, a signal pin holder can be pre-molded in a stress buffer material. For instance, an external surface of the signal pin holder, e.g., a cylindrical, electrically-conductive signal pin holder, can be at least partially pre-molded in a stress buffer material, where the stress buffer material is a material with a lower modulus of elasticity (MoE) than the EMC, and a lower MoE than the signal pin holder. In some implementations, as noted above, the signal pin holder can be formed of copper (Cu), a copper alloy, such as copper molybdenum (CuMo), or one or more other electrically conductive materials.

In example implementations, a stress buffer material can absorb stresses associated with signal pin insertion and/or thermal cycling of an associated module, which can prevent EMC cracking due such stresses. Stresses due to thermal cycling of a module can occur as a result of differences in respective coefficients of thermal expansion of signal pin holder(s) and an EMC of the module, which can be exacerbated by the respective high moduli of elasticity of the signal pin holder and the EMC. For instance, Cu can have modulus of elasticity on the order of 120 giga-pascals (GPa) with a CTE on the order of 17 parts-per-million per degree Celsius (ppm/° C.), while EMC can have a modulus of elasticity on the order of 17 GPa with a CTE of 8-10 ppm/° C. In implementations described herein, a stress buffer material, examples of which are discussed further below, can be on the order of 5 GPa or less with a CTE of 58-135 ppm/° C.

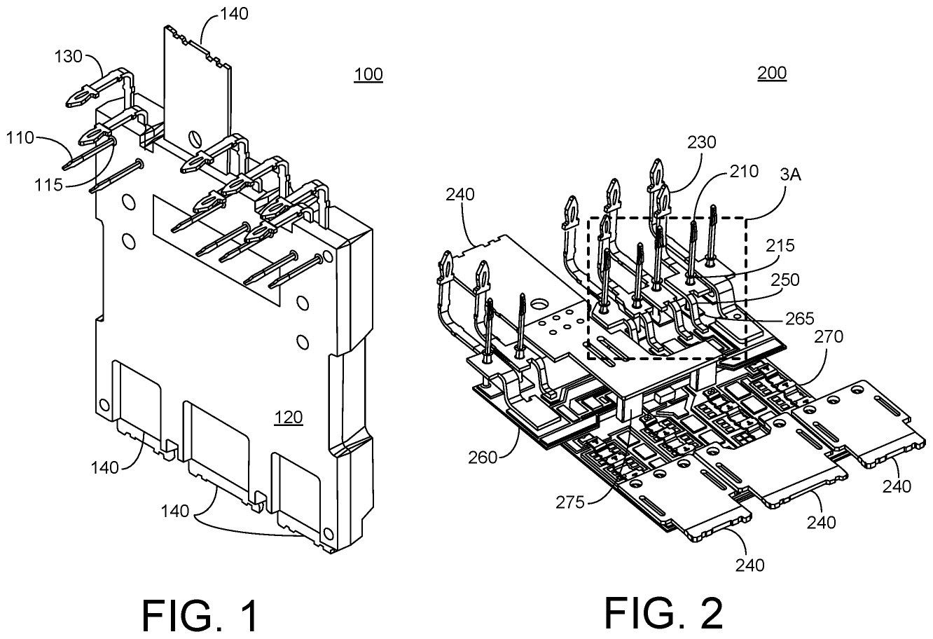

FIG. 1 is a diagram illustrating an isometric view of an example semiconductor device assembly 100. The semiconductor device assembly 100 includes a plurality of signal pins that are disposed in signal pin holders, e.g., press-fit inserted in respective signal pin holders. For example, the semiconductor device assembly 100 includes a signal pin 110 that is disposed in a signal pin holder 115. An open end of the signal pin holder 115 is exposed through a molding compound 120 of the semiconductor device assembly 100. That is, the open end of the signal pin holder 115 is accessible from outside the molding compound 120, e.g., to facilitate insertion of the signal pin 110 in the signal pin holder 115. In some implementations, as described herein, the signal pin holder 115 can include an electrically conductive, cylindrical sleeve, such as a hollow cylinder of copper or copper alloy.

As shown in FIG. 1, the semiconductor device assembly 100 also includes a plurality of bent signal pins that extend out of a side of the semiconductor device assembly 100. For instance, the semiconductor device assembly 100 includes a bent signal pin 130. In some implementations, the bent signal pin 130 (and other bent signal pins) can be optional to the signal pin 110. That is, in the view of FIG. 1, the signal pin 110 and the bent signal pin 130 can be electrically common. For instance, the signal pin holder 115 can be inserted in a through-hole defined in a signal lead structure in which the bent signal pin 130 is included. Accordingly, in the example of FIG. 1, the bent signal pin 130 can be removed, e.g., trimmed, from the semiconductor device assembly 100 in lieu of the signal pin 110. In some implementations, the signal pin 110 (and the signal pin holder 115) could be omitted, and the bent signal pin 130 could be retained. In some implementations, a combination of bent signal pins and signal pins inserted in respective signal pin holders can be included in a semiconductor device assembly. In the example of FIG. 1, the semiconductor device assembly 100 also includes a plurality of power tabs 140, which can be used for power supply connections and/or output signals, such as an output signal of a switching node of a power semiconductor module.

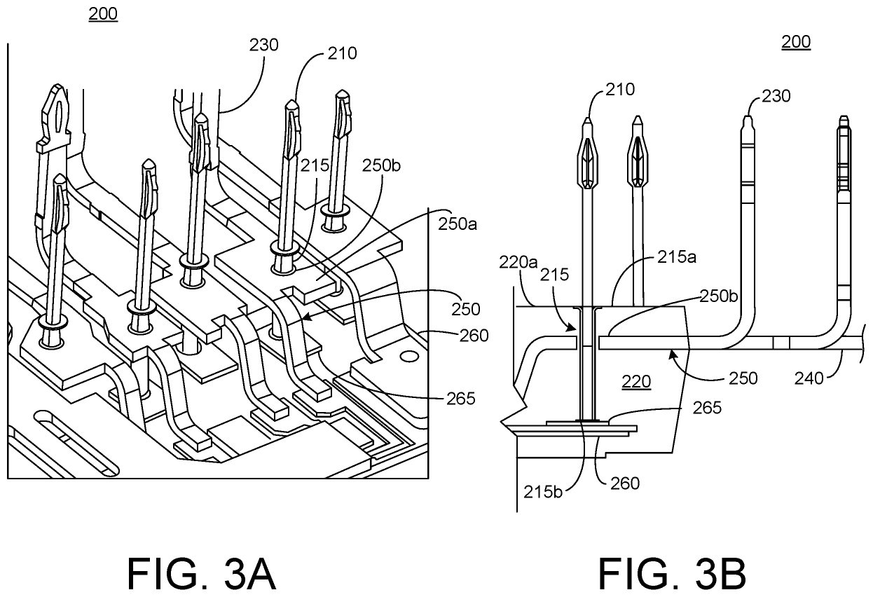

FIG. 2 is a diagram illustrating an isometric view of an example implementation of a semiconductor device assembly 200 that can be an implementation of the semiconductor device assembly 100 of FIG. 1. In FIG. 2, the semiconductor device assembly 200 is illustrated without a molding compound, such that an internal arrangement of elements of the semiconductor device assembly 200 is visible. Also in FIG. 2, a dashed line 3A indicates an inset of FIG. 2 that corresponds with FIG. 3A, which is discussed further below.

As with the semiconductor device assembly 100, the semiconductor device assembly 200 includes a plurality of signal pins that are disposed in signal pin holders, e.g., press-fit inserted in respective signal pin holders. For example, the semiconductor device assembly 200 includes a signal pin 210 that is disposed in a signal pin holder 215. The signal pin holder 215 extends through a signal lead 250 of the semiconductor device assembly 200 and is coupled to a metal layer 265 disposed on a substrate 260. In some implementations, the substrate 260 can be a PCB. The arrangement of the signal pin 210, the signal pin holder 215, the signal lead 250, the substrate 260 and the metal layer 265 is shown and discussed in further detail below with respect to FIGS. 3A and 3B.

In the example of FIG. 2, the semiconductor device assembly 200 further includes bents signal pins, such as a bent signal pin 230. Again, as with the semiconductor device assembly 100, the bent signal pins of the semiconductor device assembly 200 are shown by way of illustration, and can be alternative signal pins for respective press-fit signal pins of the semiconductor device assembly 200, such as the signal pin 210 and the bent signal pin 230. In other words, in this example, the bent signal pin 230 can be removed, e.g., trimmed, as it is redundant with the signal pin 210. In some implementations where one or more of the press-fit pins of the semiconductor device assembly 200 are not included, the associated bent signal pins shown in FIG. 2 can be retained. In some implementations, a semiconductor device assembly can include, for example, a combination of press fit signal pins (e.g., the signal pin 210 and the signal pin holder 215) and bent signal pins (e.g., the bent signal pin 230), or only press-fit signal pins.

As shown in the FIG. 2, as with the semiconductor device assembly 100, the semiconductor device assembly 200 includes a plurality of power tabs 240, which can be power supply tabs, and/or output signal tabs, e.g., for an output signal of power semiconductor device module. The semiconductor device assembly 200 also includes a semiconductor circuit assembly 270, which can include a DBM substrate or DBC substrate, and a plurality semiconductor die. In this example, the semiconductor circuit assembly 270 also includes a plurality of conductive clips for providing electrical interconnections between the semiconductor die and the substrate of the semiconductor circuit assembly 270.

The semiconductor device assembly 200 also includes a plurality of conductive posts 275 for respectively electrically coupling the plurality of power tabs 240 with the semiconductor circuit assembly 270. Further in this example, the substrate 260 is electrically coupled with the semiconductor circuit assembly 270 to respectively couple the signal pins (e.g., press-fit signal pins and/or bent signal pins) with the semiconductor circuit assembly 270.

FIGS. 3A and 3B are diagrams illustrating various views of example signal pin holders in a semiconductor device assembly, such as the assemblies of FIGS. 1 and 2. As noted above, FIG. 3A corresponds with the inset 3A in FIG. 2. FIG. 3B illustrates a side, cross-sectional view of the semiconductor device assembly 200, e.g., through the signal lead 250, the signal pin holder 215 and the signal pin 210 after a molding operation.

As shown in FIG. 3A, the signal lead 250 includes a widened portion 250a (e.g., a tag, a tab, etc.). The widened portion 250a has a through-hole 250b defined therein. The signal pin holder 215 is inserted in the through-hole 250b and extends to the substrate 260, where it is coupled to the metal layer 265 on the substrate 260, as is further illustrated in FIG. 3B. Other press-fit signal pins and holders of the semiconductor device assembly 200 can be similarly arranged, such as is shown in FIG. 3A.

As shown in the cross-sectional view of FIG. 3B, the signal pin holder 215 is inserted in the through-hole 250b of the signal lead 250. In some implementations, the signal pin holder 215 can be press-fit in the through-hole 250b, such that the signal pin holder 215 is secured (e.g., fixedly positioned) in the through-hole 250b, and electrically coupled with the signal lead 250 via frictional connection. An open end 215a of the signal pin holder 215 can be exposed through a molding compound 220 of the semiconductor device assembly 200. For instance, as shown in FIG. 3B, the open end 215a can be flanged, where the opening of the flange is coplanar with a surface 220a of the molding compound 220. The signal pin holder 215 extends through the through-hole 250b of the signal lead 250 to the substrate 260, where it is coupled with the metal layer 265. For instance, an end 215b of the signal pin holder 215 can be soldered to the metal layer 265, which can provide additional mechanical stability to the signal pin holder 215, e.g., to misalignment, such as due to tilting of the signal pin holder 215. Depending on the particular implementation, the end 215b of the signal pin holder 215 can be an open end, or can be a closed end.

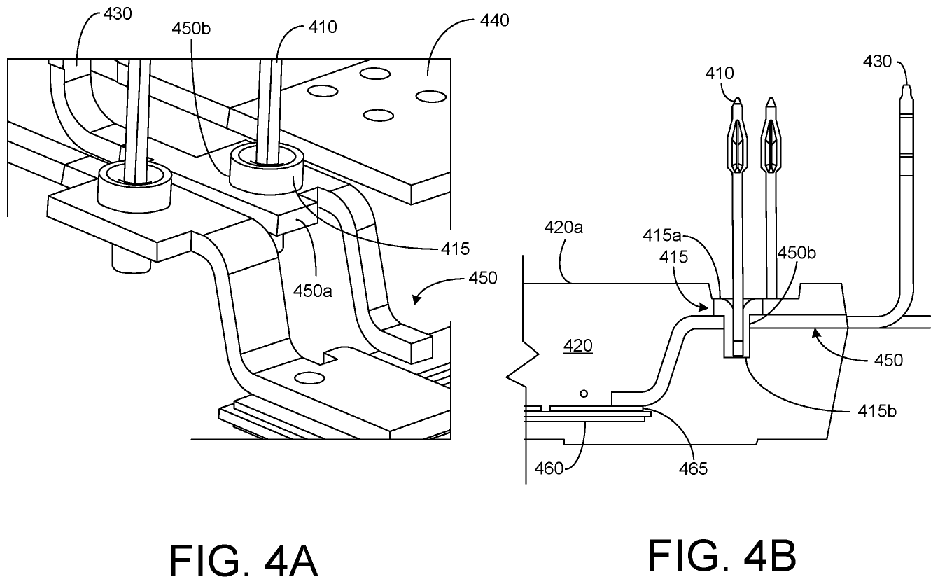

FIGS. 4A and 4B are diagrams illustrating various of views of other example signal pin holders in a semiconductor device assembly, such as the assembly of FIG. 1. Specifically, FIG. 4A illustrates an inset, isometric view of a corresponding semiconductor device assembly showing, e.g., press-fit signal pins in another signal pin holder implementation. For instance, as shown in FIG. 4A, a signal pin 410 is inserted (press-fit) in a signal pin holder 415. The signal pin holder 415 is inserted in a through-hole 450b defined in a widened portion 450a (e.g., a tag, a tab, etc.) of a signal lead 450. As with the signal pin holder 215, the signal pin holder 415 can be press-fit into the through-hole 450b, such that the signal pin holder 415 is secured (e.g., fixedly positioned), and electrically coupled with the signal lead 450 via frictional connection.

A power tab 440 is also shown in FIG. 4A by way of reference to the semiconductor device assembly 100 in FIG. 1. That is, in this example, the power tab 440 corresponds with the power tab 140 that is disposed on the top edge of the semiconductor device assembly 100 as shown in the view of FIG. 1. A bent signal pin 430 is also shown in FIG. 4A (and FIG. 4B). As with the bent signal pin 230 of the semiconductor device assembly 200, in some implementations, the bent signal pin 430 can be trimmed, e.g., when the signal pin 410 and the signal pin holder 415 are included. If a press-fit signal pin and signal pin holder are not included in a corresponding signal lead, the bent signal pin 430 can be retained, e.g., after molding, plating, etc.

FIG. 4B illustrates a side, cross-sectional view of the semiconductor device assembly of FIG. 4A after a molding operation, e.g., through the signal lead 450, the signal pin holder 415 and the signal pin 410. As shown in the cross-sectional view of FIG. 4B, the signal pin holder 415 is inserted in the through-hole 450b of the signal lead 450. As discussed above, the signal pin holder 415 can be press-fit in the through-hole 450b, such that the signal pin holder 415 is secured (e.g., fixedly positioned) in the through-hole 450b, and electrically coupled with the signal lead 450 via frictional connection.

An open end 415a of the signal pin holder 415, which can be referred to as a cap end, can be exposed through a molding compound 420 of the semiconductor device assembly of FIGS. 4A and 4B. For instance, as shown in FIG. 4B, the open end 415a can be flanged, where the opening, or top of the of the flange (the cap) in this view, is coplanar with and/or expose through a surface 420a of the molding compound 420. An opposite surface of the open end 415a, in this example, is disposed on the signal lead 450.

As shown in FIG. 4B, the signal pin holder 415 extends through the through-hole 450b of the signal lead 450 and terminates, at a closed end 415b, within the molding compound 420. That is, the closed end 415b is disposed in the molding compound 420 without being coupled to a substrate. In some implementations, the open end 415a of the signal pin holder 415 can be similarly arranged as the open end 215a of the signal pin holder 215. That is, in some implementations, the flange (cap) of the of the signal pin holder 415 can be spaced from the signal lead 450 and from the through-hole 450b. In this example, the signal lead 450 is coupled with a metal layer 465 disposed on a substrate 460, which can be a DBM substrate, a PCB, etc. Accordingly, the signal pin 410 and the signal pin holder 415 are electrically coupled with the substrate 460 via the signal lead 450.

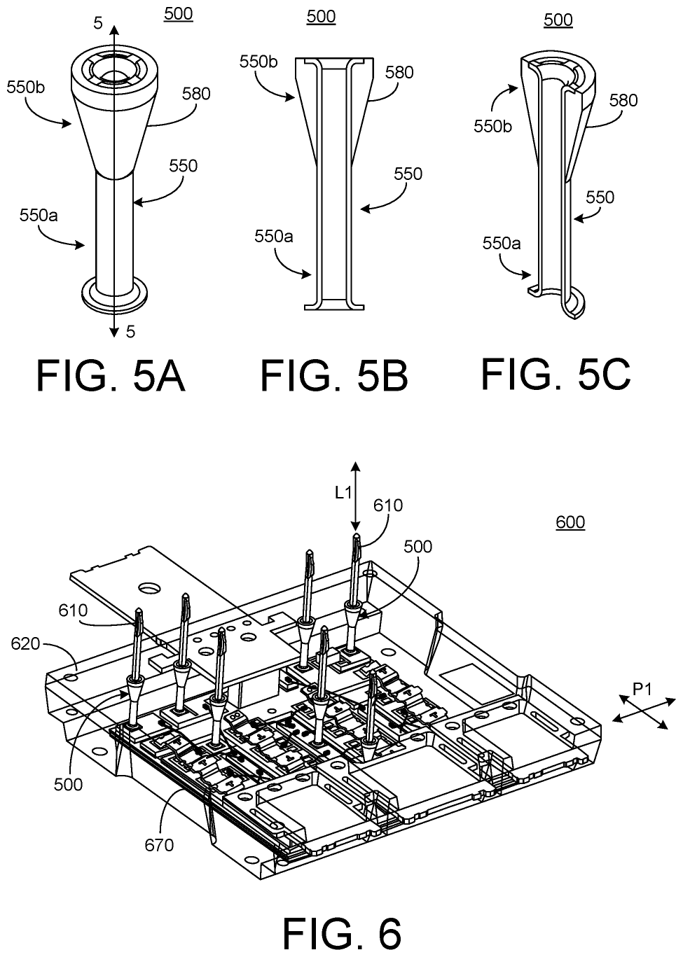

FIGS. 5A to 5C are diagrams illustrating various view of an example signal pin holder that is pre-molded with a stress buffer material, e.g., a pre-molded signal pin holder 500. FIG. 5A illustrates an isometric view of the pre-molded signal pin holder 500. FIG. 5B illustrates a cross-sectional view of the pre-molded signal pin holder 500 along the section line 5-5 in FIG. 5A. FIG. 5C illustrates an isometric view of the cross-sectioned pre-molded signal pin holder 500 shown in FIG. 5B.

As shown in FIGS. 5A-5C, the pre-molded signal pin holder 500 includes an electrically conductive signal pin holder 550 and a stress buffer material 580. In some implementations, the electrically conductive signal pin holder 550 can include Cu, CuMo, another metal, and/or another metal alloy, etc. The electrically conductive signal pin holder 550 has a proximal portion 550a, which can be coupled with a substrate of a semiconductor device circuit, such as shown in FIG. 6. The electrically conductive signal pin holder 550 also has a distal portion 550b that is pre-molded with the stress buffer material 580. For purposes of this disclosure, pre-molded indicates that the stress buffer material 580 is applied to the electrically conductive signal pin holder 550 prior to placement of the pre-molded signal pin holder 500 in a corresponding semiconductor device assembly, e.g., prior to coupling the pre-molded signal pin holder 500 to a substrate.

In this example, the stress buffer material 580 includes a conical-shaped portion and a cylindrical-shaped portion, where an open, flanged end of the distal portion 550b of the electrically conductive signal pin holder 550 is exposed through the stress buffer material 580, e.g., through its cylindrical-shaped portion. The proximal portion 550a can also include a flanged end that can be coupled with a substrate using, e.g., a solder connection. In this example, the proximal portion 550a of the electrically conductive signal pin holder 550 excludes the stress buffer material 580. That is, the proximal portion 550a is not pre-molded. As shown in FIGS. 5A-5C, the electrically conductive signal pin holder 550 is cylindrical, e.g., with flanged ends, and is configured to a receive a signal pin by press-fit insertion.

In some implementations, the stress buffer material 580 can include a material that has a modulus of elasticity that is less than a modulus of elasticity of the electrically conductive signal pin holder 550, and less than a modulus of elasticity of a molding compound used in an associated semiconductor device assembly. For instance, in some implementations the electrically conductive signal pin holder 550 can have a modulus of elasticity of greater than or equal to 100 giga-pascals (GPa), a molding compound of a corresponding assembly can have a modulus of elasticity of greater than or equal to 15 GPa, and the stress buffer material 580 can have a modulus of elasticity of less or equal to 5 GPa. By way of example, the stress buffer material 580 can include a rubber material, a polyphenylene sulfide material, and/or an engineering plastics material. For instance, in some implementations, the stress buffer material 580 can include polystyrene, polyvinyl chloride, polypropylene and polyethylene, polyetheretherketone (PEEK), etc. As discussed herein, the stress buffer material 580 can reduce stresses associated with signal pin insertion in the pre-molded signal pin holder 500, and also can reduce stresses associated with thermal cycling of an associated semiconductor device assembly. Accordingly, use of the pre-molded signal pin holder 500 in a semiconductor device assembly can reduce or prevent EMC cracking due to such stresses as compared to prior implementations.

FIG. 6 is diagram illustrating an isometric view of an example semiconductor device assembly 600 that includes a plurality of the pre-molded signal pin holder 500 of FIGS. 5A-5C. As shown in FIG. 6, signal pins 610 can be inserted respectively in the pre-molded signal pin holders 500. As can be seen, the pre-molded signal pin holders 500 can be coupled, e.g., soldered, to respective metal layers included on a substrate of a semiconductor circuit assembly 670. That is, flanged ends of respective proximal portions of the electrically conductive signal pin holders 550 can be coupled with the semiconductor circuit assembly 670.

As shown in FIG. 6, the substrate of the semiconductor circuit assembly 670 can be arranged in a plane P1, and each electrically conductive signal pin holder 550 can be arranged along a respective longitudinal axis L1 that is orthogonal to the plane P1. The semiconductor circuit assembly 670 can include a plurality of semiconductor die, as well as a plurality of conductive clips and/or a plurality of wire bonds to provide electrical interconnections for a circuit of the semiconductor circuit assembly 670. In this example, elements of the semiconductor device circuit of the semiconductor circuit assembly 670 are disposed on a same side of the substrate as the electrically conductive signal pin holders 550.

In the example of FIG. 6, the semiconductor device assembly 600 includes a molding compound 620, which is illustrated as being transparent in this view so that the internal structure of the semiconductor device assembly 600 is visible. The molding compound 620, in this example, encapsulates the semiconductor circuit assembly 670 and portions of the electrically conductive signal pin holder 550, where ends of the distal portions of the electrically conductive signal pin holder 550 are respectively exposed through (coplanar with) a primary surface of the molding compound 620, e.g., a surface in the plane P1. That is, the open ends of the distal portions 550b of the electrically conductive signal pin holders 550 and a surface of the stress buffer material 580 of each of the electrically conductive signal pin holders 550 is exposed through the molding compound 620. In other words, the open ends of the distal portions 550b of the electrically conductive signal pin holders 550 and a surface of the corresponding stress buffer material 580 are accessible outside (external to) the molding compound 620 to facilitate insertion of the signal pins 610.

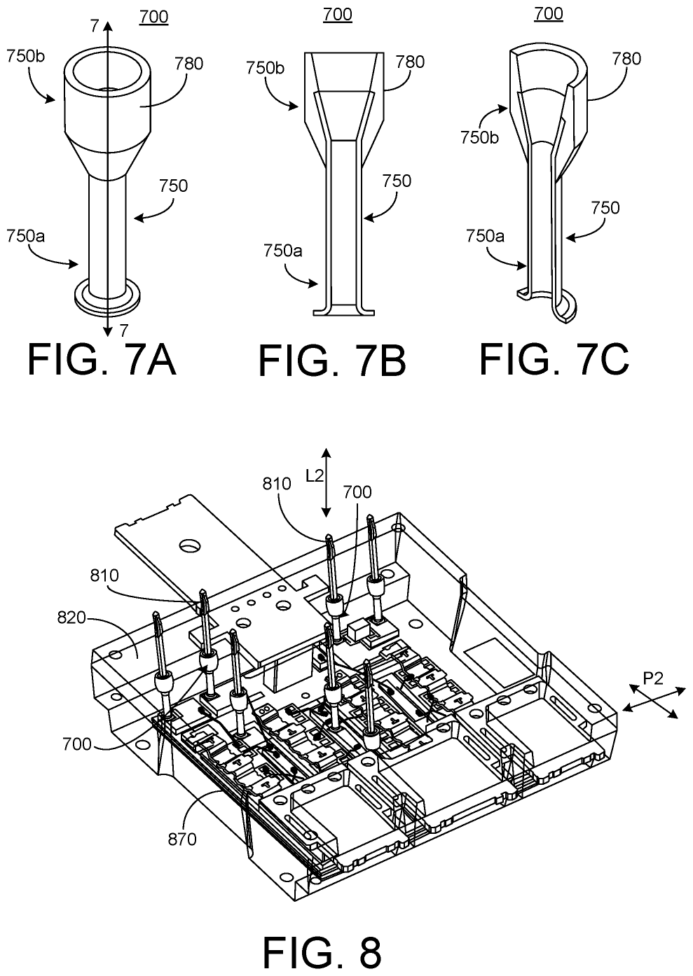

FIGS. 7A to 7C are diagrams illustrating various view of another pre-molded signal pin holder 700. FIG. 7A illustrates an isometric view of the pre-molded signal pin holder 700. FIG. 7B illustrates a cross-sectional view of the pre-molded signal pin holder 700 along the section line 7-7 in FIG. 7A. FIG. 7C illustrates an isometric view of the cross-sectioned pre-molded signal pin holder 700 shown in FIG. 7B.

As shown in FIGS. 7A-7C, the pre-molded signal pin holder 700 includes an electrically conductive signal pin holder 750 and a stress buffer material 780. In some implementations, the electrically conductive signal pin holder 750 can include Cu, CuMo, another metal, and/or another metal alloy, etc. The electrically conductive signal pin holder 750 has a proximal portion 750a, which can be coupled with a substrate of a semiconductor device circuit, such as shown in FIG. 8. The electrically conductive signal pin holder 750 also has a distal portion 750b that is pre-molded with the stress buffer material 780. As noted above, pre-molded indicates that the stress buffer material 780 is applied to the electrically conductive signal pin holder 750 prior to placement of the pre-molded signal pin holder 700 in a corresponding semiconductor device assembly, e.g., prior to coupling the pre-molded signal pin holder 700 to a substrate.

In this example, the stress buffer material 780 includes a conical-shaped portion and a cylindrical-shaped portion, where an open, flanged end of the distal portion 750b of the electrically conductive signal pin holder 750 is recessed the stress buffer material 780, e.g., recessed its cylindrical-shaped portion. As shown in FIG. 7B, the interior of the cylindrical-shaped portion of the stress buffer material stress buffer material 780 is funnel shaped. That is, the opening of the cylindrical-shaped portion has a diameter that is later than an opening in a funnel shaped end of the distal portion 750b, which, as compared to the prior implementations, can allow for increased tolerance for signal pin insertion as a result of the larger opening of the stress buffer material 780.

As shown in FIGS. 7A-7C, as with the proximal portion 550a of the electrically conductive signal pin holder 550, the proximal portion 750a of the electrically conductive signal pin holder 750 can also include a flanged end that can be coupled with a substrate using, e.g., a solder connection. In this example, the proximal portion 750a of the electrically conductive signal pin holder 750 excludes the stress buffer material 780. That is, the proximal portion 750a is not pre-molded. As shown in FIGS. 7A-76C, the electrically conductive signal pin holder 750 includes a cylindrical portion, e.g., between the funnel shaped end of the distal portion 750b and the flanged end of the proximal portion 750a, where the cylindrical-shaped portion of the electrically conductive signal pin holder 750 is configured to a receive a signal pin by press-fit insertion.

In some implementations, as with the pre-molded signal pin holder 500, the stress buffer material 780 can include a material that has a modulus of elasticity that is less than a modulus of elasticity of the electrically conductive signal pin holder 750, and less than a modulus of elasticity of a molding compound used in an associated semiconductor device assembly. For instance, in some implementations the electrically conductive signal pin holder 750 can have a modulus of elasticity of greater than or equal to 100 giga-pascals (GPa), a molding compound of a corresponding assembly can have a modulus of elasticity of greater than or equal to 15 GPa, and the stress buffer material 780 can have a modulus of elasticity of less or equal to 5 GPa. By way of example, the stress buffer material 780 can include a rubber material, a polyphenylene sulfide material, and/or an engineering plastics material, such as those described herein. As discussed herein, the stress buffer material 780 can reduce stresses associated with signal pin insertion in the pre-molded signal pin holder 700, and also can reduce stresses associated with thermal cycling of an associated semiconductor device assembly. Accordingly, use of the pre-molded signal pin holder 700 in a semiconductor device assembly can reduce or prevent EMC cracking due to such stresses as compared to prior implementations.

FIG. 8 is diagram illustrating an isometric view of an example semiconductor device assembly 800 that includes a plurality of the pre-molded signal pin holder 700 of FIGS. 7A-7C. As shown in FIG. 8, signal pins 810 can be inserted respectively in the pre-molded signal pin holders 700. As can be seen, the pre-molded signal pin holders 700 can be coupled, e.g., soldered, to respective metal layers included on a substrate of a semiconductor circuit assembly 870. That is, flanged ends of respective proximal portions of the electrically conductive signal pin holders 750 can be coupled with the semiconductor circuit assembly 870.

As shown in FIG. 8, the substrate of the semiconductor circuit assembly 870 can be arranged in a plane P2, and each electrically conductive signal pin holder 750 can be arranged along a respective longitudinal axis L2 that is orthogonal to the plane P2. The semiconductor circuit assembly 870 can include a plurality of semiconductor die, as well as a plurality of conductive clips and/or a plurality of wire bonds to provide electrical interconnections for a circuit of the semiconductor circuit assembly 870. In this example, elements of the semiconductor device circuit of the semiconductor circuit assembly 870 are disposed on a same side of the substrate as the electrically conductive signal pin holders 850.

In the example of FIG. 8, the semiconductor device assembly 800 includes a molding compound 820, which is illustrated as being transparent in this view so that the internal structure of the semiconductor device assembly 800 is visible. The molding compound 820, in this example, encapsulates the semiconductor circuit assembly 870 and portions of the electrically conductive signal pin holder 850, where open ends of the stress buffer material 780 disposed on distal portions of the electrically conductive signal pin holder 750 are respectively exposed through (coplanar with) a primary surface of the molding compound 820, e.g., a surface in the plane P2. That is, a surface of the stress buffer material 780 of each of the electrically conductive signal pin holders 750 is exposed through the molding compound 820, with the open ends of the distal portions 750b of the electrically conductive signal pin holders 750 being respectively recessed with the stress buffer material 780. In other words, the recessed open ends of the distal portions 750b of the electrically conductive signal pin holders 750 and a surface and opening of the corresponding stress buffer material 780 are accessible outside (external to) the molding compound 820 to facilitate insertion of the signal pins 810.

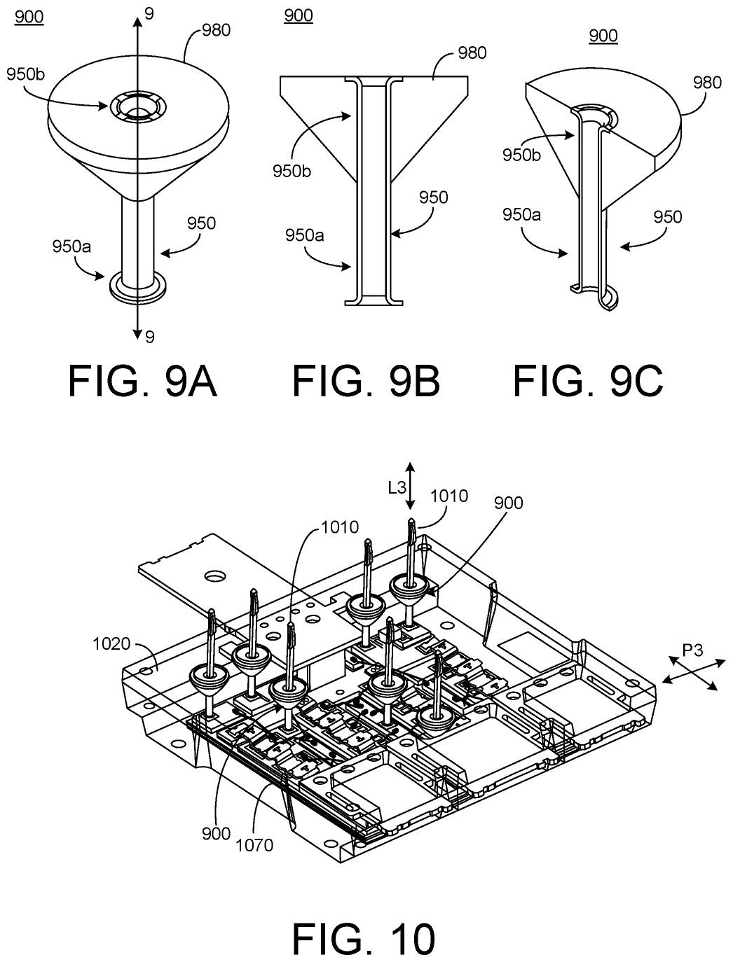

FIGS. 9A to 9C are diagrams illustrating various view of another example of a pre-molded signal pin holder 900. FIG. 9A illustrates an isometric view of the pre-molded signal pin holder 900. FIG. 9B illustrates a cross-sectional view of the pre-molded signal pin holder 900 along the section line 9-9 in FIG. 9A. FIG. 9C illustrates an isometric view of the cross-sectioned pre-molded signal pin holder 900 shown in FIG. 9B.

As shown in FIGS. 9A-9C, the pre-molded signal pin holder 900 includes an electrically conductive signal pin holder 950 and a stress buffer material 980. In some implementations, the electrically conductive signal pin holder 950 can include Cu, CuMo, another metal, and/or another metal alloy, etc. The electrically conductive signal pin holder 950 has a proximal portion 950a, which can be coupled with a substrate of a semiconductor device circuit, such as shown in FIG. 10. The electrically conductive signal pin holder 950 also has a distal portion 950b that is pre-molded with the stress buffer material 980. As noted above, pre-molded indicates that the stress buffer material 980 is applied to the electrically conductive signal pin holder 950 prior to placement of the pre-molded signal pin holder 900 in a corresponding semiconductor device assembly, e.g., prior to coupling the pre-molded signal pin holder 900 to a substrate.

In this example, the stress buffer material 980 includes a conical-shaped portion and a cylindrical-shaped portion, where an open, flanged end of the distal portion 950b of the electrically conductive signal pin holder 950 is exposed through the stress buffer material 980, e.g., through its cylindrical-shaped portion. The proximal portion 950a can also include a flanged end that can be coupled with a substrate using, e.g., a solder connection. In this example, the proximal portion 950a of the electrically conductive signal pin holder 950 excludes the stress buffer material 980. That is, the proximal portion 950a is not pre-molded. As shown in FIGS. 9A-9C, the electrically conductive signal pin holder 950 is cylindrical, e.g., with flanged ends, and is configured to a receive a signal pin by press-fit insertion. As compared with the stress buffer material 580 of the pre-molded signal pin holder 500, the stress buffer material 780 of the pre-molded signal pin holder 700 has a larger diameter. In implementations where there is sufficient space between signal pins, use of the stress buffer material 980 with a wider diameter can facilitate further reduction of EMC crack inducing stresses in an associated semiconductor device assembly 100.

In some implementations, the stress buffer material 980 can include a material that has a modulus of elasticity that is less than a modulus of elasticity of the electrically conductive signal pin holder 950, and less than a modulus of elasticity of a molding compound used in an associated semiconductor device assembly. For instance, in some implementations the electrically conductive signal pin holder 950 can have a modulus of elasticity of greater than or equal to 100 giga-pascals (GPa), a molding compound of a corresponding assembly can have a modulus of elasticity of greater than or equal to 15 GPa, and the stress buffer material 980 can have a modulus of elasticity of less or equal to 5 GPa. By way of example, the stress buffer material 980 can include a rubber material, a polyphenylene sulfide material, and/or an engineering plastics material, such as the examples described herein. As discussed herein, the stress buffer material 980 can reduce stresses associated with signal pin insertion in the pre-molded signal pin holder 900, and also can reduce stresses associated with thermal cycling of an associated semiconductor device assembly. Accordingly, use of the pre-molded signal pin holder 900 in a semiconductor device assembly can reduce or prevent EMC cracking due to such stresses as compared to prior implementations.

FIG. 10 is diagram illustrating an isometric view of an example semiconductor device assembly 1000 that includes a plurality of the pre-molded signal pin holder 900 of FIGS. 9A-9C. As shown in FIG. 10, signal pins 1010 can be inserted respectively in the pre-molded signal pin holders 900. As can be seen, the pre-molded signal pin holders 900 can be coupled, e.g., soldered, to respective metal layers included on a substrate of a semiconductor circuit assembly 1070. That is, flanged ends of respective proximal portions of the electrically conductive signal pin holders 950 can be coupled with the semiconductor circuit assembly 1070.

As shown in FIG. 10, the substrate of the semiconductor circuit assembly 1070 can be arranged in a plane P3, and each electrically conductive signal pin holder 950 can be arranged along a respective longitudinal axis L3 that is orthogonal to the plane P3. The semiconductor circuit assembly 1070 can include a plurality of semiconductor die, as well as a plurality of conductive clips and/or a plurality of wire bonds to provide electrical interconnections for a circuit of the semiconductor circuit assembly 1070. In this example, elements of the semiconductor device circuit of the semiconductor circuit assembly 1070 are disposed on a same side of the substrate as the electrically conductive signal pin holders 950.

As shown in FIG. 10, the semiconductor device assembly 1000 includes a molding compound 1020, which is illustrated as being transparent in this view so that the internal structure of the semiconductor device assembly 1000 is visible. The molding compound 1020, in this example, encapsulates the semiconductor circuit assembly 1070 and portions of the electrically conductive signal pin holder 950, where ends of the distal portions of the electrically conductive signal pin holder 950 are respectively exposed through (coplanar with) a primary surface of the molding compound 1020, e.g., a surface in the plane P3. That is, the open ends of the distal portions 950b of the electrically conductive signal pin holders 950 and a surface of the stress buffer material 980 of each of the electrically conductive signal pin holders 950 is exposed through the molding compound 1020. In other words, the open ends of the distal portions 950b of the electrically conductive signal pin holders 950 and a surface of the corresponding stress buffer material 980 are accessible outside (external to) the molding compound 1020 to facilitate insertion of the signal pins 1010.

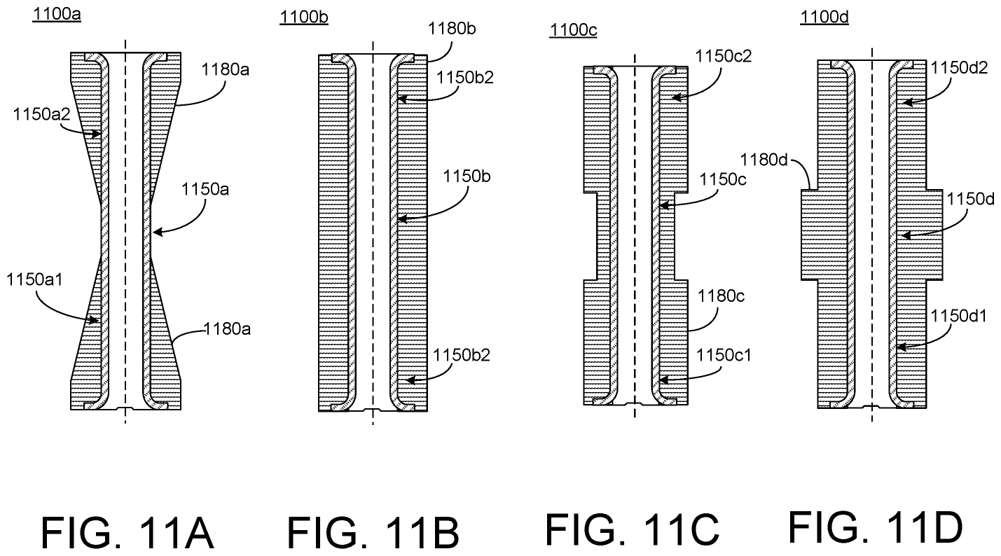

FIGS. 11A to 11D are diagrams illustrating examples of other pre-molded signal pin holders, respectively a pre-molded signal pin holder 1100a, a pre-molded signal pin holder 1100b, a pre-molded signal pin holder 1100c, and a pre-molded signal pin holder 1100d. Referring to FIG. 11A, the pre-molded signal pin holder 1100a includes an electrically conductive signal pin holder 1150a with a proximal portion 1150a1, including a flanged end for attachment to a substrate, and a distal portion 1150a2, with a flanged end for receiving a signal pin. In the pre-molded signal pin holder 1100a of FIG. 11A, the electrically conductive signal pin holder 1150a can be pre-molded with a stress buffer material 1180a on both the proximal portion 1150a1 and the distal portion 1150a2. Further in this example, a portion of the electrically conductive signal pin holder 1150a disposed between the respective portions of the stress buffer material 1180a on the proximal portion 1180a1 and the distal portion 1180a2 excludes the stress buffer material 1180a. The stress buffer material 1180a on each of the proximal portion 1150a1 and the distal portion 1150a2 in the example of FIG. 11A, has similar shape as the stress buffer material 580 of the pre-molded signal pin holder 500, but is mirrored on the proximal portion 1150a1, as compared to the pre-molded signal pin holder 500, where the proximal portion 550a excludes the stress buffer material 580.

Referring to FIG. 11B, the pre-molded signal pin holder 1100b includes an electrically conductive signal pin holder 1150b with a proximal portion 1150b1, including a flanged end for attachment to a substrate, and a distal portion 1150b2, with a flanged end for receiving a signal pin. In the pre-molded signal pin holder 1100b of FIG. 11B, both the proximal portion 1150b1 and the distal portion 1150b2 can be pre-molded with a stress buffer material 1180b, with the stress buffer material 1180b having a constant diameter along a length of the electrically conductive signal pin holder 1150b.

Referring to FIG. 11C, the pre-molded signal pin holder 1100c includes an electrically conductive signal pin holder 1150c with a proximal portion 1150c1, including a flanged end for attachment to a substrate, and a distal portion 1150c2, with a flanged end for receiving a signal pin. In the pre-molded signal pin holder 1100c of FIG. 11C, both the proximal portion 1150c1 and the distal portion 1150c2 can be pre-molded with a stress buffer material 1180c, with the stress buffer material 1180c having a having a portion with a narrower diameter along a portion of the electrically conductive signal pin holder 1150c between portions of the stress buffer material 1180c with a larger diameter disposed on the proximal portion 1150c1 and the distal portion 1150c2.

Referring to FIG. 11D, the pre-molded signal pin holder 1100d includes an electrically conductive signal pin holder 1150d with a proximal portion 1150d1, including a flanged end for attachment to a substrate, and a distal portion 1150d2, with a flanged end for receiving a signal pin. In the pre-molded signal pin holder 1100d of FIG. 11D, both the proximal portion 1150d1 and the distal portion 1150d2 can be pre-molded with a stress buffer material 1180d, with the stress buffer material 1180d having a having a portion with a larger diameter along a portion of the electrically conductive signal pin holder 1150d between portions of the stress buffer material 1180d with a smaller diameter that are disposed on the proximal portion 1150d1 and the distal portion 1150d2. The various arrangements of FIGS. 11A-11D can improve adhesion between a pre-molded signal holder (1100a, 1100b, 1100c, 1100d) and an EMC of an associated semiconductor device assembly.

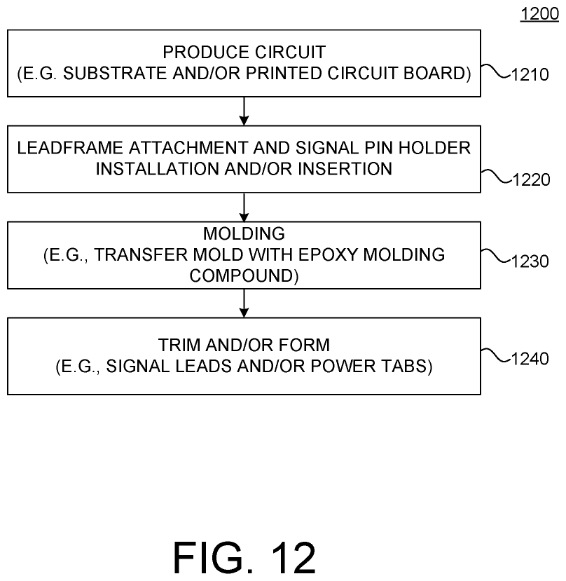

FIG. 12 is a flowchart illustrating a method 1200 for producing a semiconductor assembly, such as, e.g., the assemblies of FIGS. 1, 2, 3A-3B, 4A-4B, 6, 8 and 10. The operations of the method 1200 are given by way of example, and for purposes of illustration. In some implementations, additional operations can be included, sub-operations can be performed, or one or more operations can be omitted. For example, a signal pin insertion operation can be included in the method 1200, where the signal pins can be press-fit into respective signal pin holders included in a semiconductor device assembly produced by the method 1200.

The method 1200 includes, at block 1210, producing a circuit assembly, such as the substrate 260 and semiconductor circuit assembly 270 of FIG. 2, the semiconductor circuit assembly 670 of FIG. 6, the semiconductor circuit assembly 870 of FIG. 8, or the semiconductor circuit assembly 1070 of FIG. 10. The operation at block 1210 can include a number of sub-operations, such as attaching, e.g., sintering, semiconductor die to a substrate, attaching conducive clips, performing at least one solder reflow operation, forming wire bonds, etc. At block 1220, the method 1200 includes leadframe attachment and signal pin holder installation and/or insertion into through-holes in signal leads of the leadframe. The method 1200, at block 1220, can also include a solder reflow operation.

At block 1230, the method 1200 includes molding (e.g., transfer molding) the semiconductor device assembly in an EMC, such as for the example semiconductor device assemblies described herein. At block 1240, the method 1200 includes a trimming and/or forming operation, where portions of signal lead used for bent signal pins are either trimmed for a single body leadframe and formed to produce bent signal pins, such as the bent signal pin 130, the bent signal pin 230, or the bent signal pin 430, e.g., for signal leads in which a signal pin holder is not installed. For signal leads having a signal pin holder, the corresponding portion of the signal lead outside the molding compound can be trimmed, e.g., removed.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An electronic device assembly comprising:
a circuit including at least one semiconductor die;
a signal lead electrically coupled with the circuit, the signal lead having a hole defined therethrough;
an electrically conductive signal pin holder disposed in the hole of the signal lead, the electrically conductive signal pin holder being electrically coupled with the signal lead; and
a molding compound encapsulating, at least:
the circuit;
a portion of the signal lead including the hole; and
a portion of the electrically conductive signal pin holder, an open end of the electrically conductive signal pin holder being accessible outside the molding compound.

2. The electronic device assembly of claim 1, wherein:
the open end of the electrically conductive signal pin holder is a first end,
the circuit includes a substrate, and
the electrically conductive signal pin holder includes a second end that is disposed on the substrate.

3. The electronic device assembly of claim 2, wherein the second end of the electrically conductive signal pin holder is coupled with the substrate via a solder connection.

4. The electronic device assembly of claim 1, wherein:
the open end of the electrically conductive signal pin holder is a first end, and
the electrically conductive signal pin holder includes a second end that is closed and disposed within the molding compound.

5. The electronic device assembly of claim 1, wherein the open end of the electrically conductive signal pin holder is coplanar with a surface of the molding compound.

6. The electronic device assembly of claim 1, wherein the electrically conductive signal pin holder is cylindrical and is configured to a receive a signal pin by press-fit insertion.

7. The electronic device assembly of claim 1, wherein the electrically conductive signal pin holder is fixedly positioned in the hole of the signal lead by a frictional connection.

8. The electronic device assembly of claim 1, wherein the open end of the electrically conductive signal pin holder includes a flange, a first surface of the flange being disposed on the signal lead, and a second surface of the flange, opposite the first surface, being coplanar with a surface of the molding compound.

9. The electronic device assembly of claim 1, wherein the signal lead and the electrically conductive signal pin holder include at least one of copper or a copper alloy.

10. An electronic device assembly comprising:
a substrate arranged in a plane, the substrate having a first side and a second side, the second side being opposite the first side;
at least one semiconductor die disposed on the first side of the substrate; and
an electrically conductive signal pin holder including:
a proximal portion coupled with the first side of the substrate; and
a distal portion,
at least a portion of the electrically conductive signal pin holder being pre-molded in a stress buffer material, and
the electrically conductive signal pin holder being arranged along a longitudinal axis that is orthogonal to the plane of the substrate.

11. The electronic device assembly of claim 10, wherein:
the distal portion of the electrically conductive signal pin holder is pre-molded in the stress buffer material; and
the proximal portion of the electrically conductive signal pin holder excludes the stress buffer material.

12. The electronic device assembly of claim 10, wherein the proximal portion of the electrically conductive signal pin holder includes a flange, the flange being coupled to the first side of the substrate via a solder connection.

13. The electronic device assembly of claim 10, further comprising a molding compound encapsulating the substrate, the at least one semiconductor die, and the electrically conductive signal pin holder, such that a surface of the stress buffer material is exposed through the molding compound, an open end of the electrically conductive signal pin holder being exposed through the stress buffer material.

14. The electronic device assembly of claim 13, wherein the stress buffer material has a modulus of elasticity that is less than a modulus of elasticity of the electrically conductive signal pin holder, and less than a modulus of elasticity of the molding compound.

15. The electronic device assembly of claim 13, wherein:
the electrically conductive signal pin holder has a modulus of elasticity of greater than or equal to 100 giga-pascals (GPa),
the molding compound has a modulus of elasticity of greater than or equal to 15 GPa, and
the stress buffer material has a modulus of elasticity of less or equal to 5 GPa.

16. The electronic device assembly of claim 10, wherein the electrically conductive signal pin holder is cylindrical and is configured to a receive a signal pin by press-fit insertion.

17. The electronic device assembly of claim 10, wherein the stress buffer material includes one of:
a rubber material;
a polyphenylene sulfide material; or
an engineering plastics material.

18. The electronic device assembly of claim 10, wherein the electrically conductive signal pin holder includes at least one of:
copper; or
a copper alloy.

19. A method of forming an electronic device assembly, the method comprising:
producing, on a substrate, a semiconductor device circuit;
coupling a signal lead with the substrate, the signal lead having a hole defined therethrough;
press-fitting an electrically conductive signal pin holder in the hole of the signal lead; and
performing a molding operation to encapsulate, in a molding compound, at least:
the semiconductor device circuit;
a portion of the signal lead including the hole; and
a portion of the electrically conductive signal pin holder, an open end of the electrically conductive signal pin holder being accessible outside the molding compound.

20. The method of claim 19, further comprising press-fitting a signal pin into the electrically conductive signal pin holder via the open end.

21. The method of claim 19, wherein the open end of the electrically conductive signal pin holder is a first end, the method further comprising coupling a second end of the electrically conductive signal pin holder to the substrate via a solder connection.

22. The method of claim 19, wherein the portion of the signal lead including the hole is a first portion,
the method further comprising, after the molding operation, trimming the signal lead to remove a portion of the signal lead that is external to the molding compound.
